(19) United States
(12) Patent Application Publication
(10) Pub. No.: US 2026/0136930 A1
(43) Pub. Date: May 14, 2026

(54) ELECTRONIC PACKAGES AND ELECTRONIC DEVICES FOR MOUNTING TO A CIRCUIT BOARD

(71) Applicant: Skyworks Solutions, Inc., Irvine, CA (US)

(72) Inventors: Howard E. Chen, Anaheim, CA (US); Jeffrey Sailer, Cedar Rapids, IA (US)

(21) Appl. No.: 19/387,355

(22) Filed: Nov. 12, 2025

Related U.S. Application Data
(60) Provisional application No. 63/719,800, filed on Nov. 13, 2024.
(60) Provisional application No. 63/720,070, filed on Nov. 13, 2024.

(51) Int. Cl. H01L 23/373; H01L 23/00; H01L 23/498

(52) U.S. Cl. CPC H10W 40/258; H10W 70/635; H10W 90/701; H10W 90/724

(57) ABSTRACT

There is provided an electronic package for mounting to a circuit board. The electronic package comprises a substrate having opposed first and second sides, at least one semiconductor component disposed on the first side of the substrate, a grid of electrically conductive nodes arranged on the second side of the substrate at a predetermined pitch, and at least one thermally conductive element disposed on the second side of the substrate. The thermally conductive element is coupled to at least one thermally conductive pathway. The thermally conductive pathway extends between the semiconductor component and the second side of the substrate through a thickness of the substrate to define at least one of the electrically conductive nodes and thermally couple the semiconductor component to the thermally conductive element. The thermally conductive element extends over the second side of the substrate by a distance of greater than or equal to the predetermined pitch.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

The present disclosure relates to an electronic package for mounting to a circuit board. The present disclosure also relates to an electronic device comprising an electronic sub-assembly, in which the electronic sub-assembly has an electronic package mounted to a circuit board. The present disclosure also relates to a method of manufacturing an electronic package for mounting to a circuit board.

### Description of the Related Technology

Conventional electronic packages have at least one semiconductor component mounted to a first side of a substrate. An array of solder balls is arranged on a second side of the substrate, the second side opposed to the first side. The semiconductor component is typically at least partially encapsulated within a mold structure provided on the first side of the substrate. In use, the semiconductor component will generate heat. During operation, heat from the semiconductor component is conducted through the thickness of the substrate, for example along copper vias incorporated into the structure of the substrate, into distinct ones of the array of solder balls.

### SUMMARY

According to one embodiment there is provided an electronic package for mounting to a circuit board, the electronic package including a substrate having opposed first and second sides, at least one semiconductor component disposed on the first side of the substrate, a grid of electrically conductive nodes arranged on the second side of the substrate at a predetermined pitch, and at least one thermally conductive element disposed on the second side of the substrate. The thermally conductive element is coupled to at least one thermally conductive pathway. The thermally conductive pathway extends between the semiconductor component and the second side of the substrate through a thickness of the substrate to define at least one of the electrically conductive nodes and thermally couple the semiconductor component to the thermally conductive element. The thermally conductive element extends over the second side of the substrate by a distance of greater than or equal to the predetermined pitch.

In one example the at least one thermally conductive pathway comprises at least first and second thermally conductive pathways extending between the semiconductor component and the second side of the substrate through the thickness of the substrate, each of the first and second thermally conductive pathways thermally coupling the semiconductor component to the thermally conductive element. In one example each of the first and second thermally conductive pathways define respective ones of the electrically conductive nodes. In one example the thermally conductive pathway comprises an intra-substrate portion extending between the opposed first and second sides of the substrate.

In one example the thermally conductive element is integrally formed as a unitary piece with the intra-substrate portion.

In one example the thermally conductive element is electroplated onto the intra-substrate portion.

In one example the thermally conductive pathway comprises a first intermediate element thermally coupling the intra-substrate portion of the thermally conductive pathway to the semiconductor component.

In one example the first intermediate element comprises or consists of a solder ball.

In one example the first intermediate element is substantially formed of a non-solder material.

In one example the first intermediate element is substantially formed of copper.

In one example the first intermediate element comprises or consists of a metallic post substantially formed of the non-solder material.

In one example the thermally conductive pathway comprises a second intermediate element thermally coupling the intra-substrate portion of the thermally conductive pathway to the thermally conductive element.

In one example the second intermediate element comprises or consists of a solder ball.

In one example the second intermediate element is substantially formed of a non-solder material.

In one example the second intermediate element is substantially formed of copper.

In one example the second intermediate element comprises or consists of a metallic post substantially formed of the non-solder material.

In one example the intra-substrate portion and the thermally conductive element are formed of the same material.

In one example the intra-substrate portion and the thermally conductive element are each substantially formed of copper.

In one example the intra-substrate portion comprises a metallic contact pad disposed on the second side of the substrate.

In one example the metallic contact pad defines one of the grid of electrically conductive nodes.

In one example the intra-substrate portion further comprises a via extending from the first side of the substrate, the metallic contact pad coupled to the via.

In one example the metallic contact pad is integrally formed as a unitary piece with the via.

In one example the at least one semiconductor component comprises first and second semiconductor components disposed on the first side of the substrate.

In one example a first one or set of thermally conductive pathways extends between the first semiconductor component and the thermally conductive element and a second one or set of thermally conductive pathways extends between the second semiconductor component and the thermally conductive element to thereby thermally couple each of the first and second semiconductor components to the thermally conductive element.

In one example the thermally conductive element is substantially formed of copper.

In one example the thermally conductive element is disposed on the second side of the substrate to lie within a surface area footprint of the semiconductor component disposed on the first side of the substrate.

In one example the thermally conductive element has a length dimension that is greater than 60%, or 70%, or 80% of a length or a width dimension of the semiconductor component.

In one example a length dimension of the thermally conductive element is no more than 110%, or 100%, or 90% of a length dimension of the semiconductor component.

In one example the thermally conductive element extends away from the second side of the substrate to a height of no more than 130 microns, or no more than 120 microns, or no more than 110 microns, or no more than 100 microns.

In one example the thermally conductive element has a shape defining a parallelepiped.

In one example the thermally conductive element defines an elongate strip or bar.

In one example the at least one thermally conductive element comprises a group of thermally conductive elements disposed on the second side of the substrate, each one of the group of thermally conductive elements coupled to at least one corresponding thermally conductive pathway extending between the semiconductor component and the respective thermally conductive element.

In one example the group of thermally conductive elements is disposed on the second side of the substrate to lie within a surface area footprint of the semiconductor component disposed on the first side of the substrate.

In one example a second side mold structure extends over at least part of the second side of the substrate to at least partially encapsulate the thermally conductive element.

In one example a face of the thermally conductive element is exposed through the second side mold structure.

In one example the exposed face of the thermally conductive element is flush with an exposed surface of the second side mold structure.

In one example the thermally conductive pathway is configured to define a signal pathway for providing one or both of data or electronic signals to and/or from the semiconductor component.

In one example first and second ones of the thermally conductive pathways are in surface contact with respective first and second surface regions of the semiconductor component.

In one example the electronic package is a dual-sided electronic package.

In one example one or more solder portions are disposed on an exposed surface of the thermally-conductive element for coupling the electronic package to a separate circuit board.

According to another embodiment there is provided an electronic device comprising an electronic sub-assembly, the electronic sub-assembly comprising: a circuit board; and an electronic package mounted to the circuit board. The electronic package includes a substrate having opposed first and second sides, at least one semiconductor component disposed on the first side of the substrate, a grid of electrically conductive nodes arranged on the second side of the substrate at a predetermined pitch, and at least one thermally conductive element disposed on the second side of the substrate. The thermally conductive element is coupled to at least one thermally conductive pathway. The thermally conductive pathway extends between the semiconductor component and the second side of the substrate through a thickness of the substrate to define at least one of the electrically conductive nodes and thermally couple the semiconductor component to the thermally conductive element. The thermally conductive element extends over the second side of the substrate by a distance of greater than or equal to the predetermined pitch.

In one example the electronic device is a wireless mobile device.

In one example electronic device further comprises one or more interconnection elements extending between the thermally conductive element and the circuit board to thereby thermally couple the thermally conductive element to the circuit board. In one example the interconnection element comprises or consists of a portion of solder.

According to another embodiment there is provided a method for manufacturing an electronic package for mounting to a circuit board, the method comprising steps of providing a substrate having opposed first and second sides, a grid of electrically conductive nodes arranged on the second side of the substrate at a predetermined pitch. The method further includes arranging or forming a thermally conductive element on the second side of the substrate to be in thermal communication with at least one thermally conductive path extending through a thickness of the substrate to define at least one of the electrically conductive nodes. The thermally conductive element extends over the second side of the substrate by a distance of greater than or equal to the predetermined pitch. The method further includes arranging at least one semiconductor component on the first side of the substrate to be in thermal communication with the least one thermally conductive path.

In one example the at least one thermally conductive path comprises at least first and second thermally conductive paths extending through the thickness of the substrate, the step of arranging or forming a thermally conductive element on the second side of the substrate performed such that the thermally conductive element is in thermal communication with each of the first and second thermally conductive paths, the step of arranging at least one semiconductor component on the first side of the substrate performed such that the semiconductor component is in thermal communication with each of the first and second thermally conductive paths. In one example each of the first and second thermally conductive paths define respective ones of the electrically conductive nodes.

In one example the step of arranging or forming a thermally conductive element on the second side of the substrate to be in thermal communication with at least one thermally conductive path extending through a thickness of the substrate comprises integrally forming the thermally conductive element as a unitary piece with the thermally conductive path. In one example the step of integrally forming the thermally conductive element as a unitary piece with the thermally conductive path comprises electroplating onto the thermally conductive path to progressively build up and form the thermally conductive element.

In one example the step of arranging at least one semiconductor component on the first side of the substrate to be in thermal communication with the thermally conductive path comprises positioning a first thermally conductive intermediate element between the semiconductor component and the thermally conductive path.

In one example the first thermally conductive intermediate element comprises or consists of a solder ball.

In one example the first thermally conductive intermediate element is substantially formed of a non-solder material.

In one example the first thermally conductive intermediate element is substantially formed of copper.

In one example the first thermally conductive intermediate element comprises or consists of a metallic post substantially formed of the non-solder material.

In one example the step of arranging or forming a thermally conductive element on the second side of the substrate to be in thermal communication with at least one thermally conductive path extending through a thickness of the substrate comprises positioning a second thermally conductive intermediate element between the thermally conductive path and the thermally conductive element.

In one example the second thermally conductive intermediate element comprises or consists of a solder ball.

In one example the second thermally conductive intermediate element is substantially formed of a non-solder material.

In one example the second thermally conductive intermediate element is substantially formed of copper.

In one example the second thermally conductive intermediate element comprises or consists of a metallic post substantially formed of the non-solder material.

In one example the thermally conductive path and the thermally conductive element are formed of the same material.

In one example the thermally conductive path and the thermally conductive element are each substantially formed of copper.

In one example the step of arranging at least one semiconductor component on the first side of the substrate to be in thermal communication with the thermally conductive path comprises arranging first and second semiconductor components on the first side of the substrate to be in thermal communication with respective first and second ones or sets of thermally conductive paths extending through the thickness of the substrate.

In one example the step of arranging or forming a thermally conductive element on the second side of the substrate to be in thermal communication with at least one thermally conductive path extending through a thickness of the substrate comprises arranging or forming the thermally conductive element on the second side of the substrate to be in thermal communication with each of the first and second ones or sets of thermally conductive paths.

In one example the thermally conductive element is substantially formed of copper.

In one example the step of arranging or forming a thermally conductive element on the second side of the substrate is performed such that the thermally conductive element is disposed on the second side of the substrate to lie within a surface area footprint of the semiconductor component disposed on the first side of the substrate.

In one example the thermally conductive element has a length dimension that is greater than 60%, or 70%, or 80% of a length or a width dimension of the semiconductor component.

In one example a length dimension of the thermally conductive element is no more than 110%, or 100%, or 90% of a length dimension of the semiconductor component.

In one example the thermally conductive element extends away from the second side of the substrate to a height of no more than 130 microns, or no more than 120 microns, or no more than 110 microns, or no more than 100 microns.

In one example the thermally conductive element has a shape defining a parallelepiped.

In one example the thermally conductive element defines an elongate strip or bar.

In one example the step of arranging or forming a thermally conductive element on the second side of the substrate to be in thermal communication with at least one thermally conductive path extending through a thickness of the substrate comprises arranging each one of a group of thermally conductive elements on the second side of the substrate to be in thermal communication with at least one corresponding thermally conductive path extending between the semiconductor component and the respective thermally conductive element.

In one example the step of arranging each one of a group of thermally conductive elements on the second side of the substrate is performed such that the group of thermally conductive bodies is disposed on the second side of the substrate to lie within a surface area footprint of the semiconductor component disposed on the first side of the substrate.

In one example the method further comprises a step of arranging a second side mold structure over at least part of the second side of the substrate to at least partially encapsulate the thermally conductive element.

In one example the step of arranging a second side mold structure over at least part of the second side of the substrate fully encapsulates the thermally conductive element within the second side mold structure.

In one example the method further comprises a step of removing a portion of the second side mold structure to expose a face of the thermally conductive element through the second side mold structure.

In one example the step of removing a portion of the second side mold structure is performed such that the exposed face of the thermally conductive element is flush with an exposed surface of the second side mold structure.

In one example the method further comprises a step of disposing one or more interconnection elements on an exposed surface of the thermally-conductive element for coupling the electronic package to a separate circuit board. In one example the interconnection element comprises a solder portion.

In one example the electronic package resulting from the method is a dual-sided electronic package.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment”, “some embodiments”, “an alternate embodiment”, “various embodiments”, “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1 is a cross-sectional schematic view of an electronic package according to the background art, being a view through section A-A of FIG. 2.

FIG. 2 is a plan schematic view of the bottom side of the electronic package of FIG. 1.

FIG. 3 is a cross-sectional schematic view of a first example of an electronic package according to aspects of the present disclosure, being representative of a view through any one of sections B-B, B′-B′, and B″-B″ of FIG. 4.

FIG. 4 is a plan schematic view of the bottom side of the electronic package of FIG. 3.

FIG. 5 is a plan schematic view of the bottom side of a further example of an electronic package according to aspects of the present disclosure;

FIG. 6 is a cross-sectional schematic view of a further example of an electronic package according to aspects of the present disclosure, being representative of a view through any one of sections B-B, B′-B′, and B″-B″ of FIG. 4.

FIG. 7 is a cross-sectional schematic view of a further example of an electronic package according to aspects of the present disclosure.

FIG. 8 is a cross-sectional schematic view of a further example of an electronic package according to aspects of the present disclosure.

FIG. 9 is a cross-sectional schematic view of the electronic package of FIG. 3 mounted to a separate circuit board to form an electronic sub-assembly.

FIG. 10 is a cross-sectional schematic view of the electronic package of FIG. 6 mounted to a separate circuit board to form an electronic sub-assembly.

FIG. 11 is a flow chart illustrating an exemplary method of manufacturing an electronic package, for example the electronic package of FIGS. 3, 6, 7 or 8, according to aspects of the present disclosure.

FIG. 12 shows one or more electronic packages mounted on a wireless phone board that can include one or more features described herein.

FIG. 13 schematically depicts the wireless phone board with an electronic package according to the present disclosure installed thereon.

FIG. 14 schematically depicts a wireless device incorporating the wireless phone board of FIG. 13 with the electronic package installed thereon.

### DETAILED DESCRIPTION

Aspects and embodiments described herein are directed to an electronic package, preferably a dual-sided electronic package, for mounting to a circuit board. Aspects and embodiments described herein are also directed to an electronic device including an electronic package. Aspects and embodiments described herein are also directed to a method for manufacturing an electronic package for mounting to a circuit board. Aspects and embodiments described herein provide for conducting heat away from a semiconductor component of an electronic package during operation of the semiconductor component.

It is to be appreciated that embodiments of the packages, devices and methods discussed herein are not limited in application to the details of construction and the arrangement of components set forth in the following description or illustrated in the accompanying drawings. The packages, devices and methods are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including”, “comprising”, “having”, “containing”, “involving”, and variations thereof is meant to encompass the items listed thereafter and equivalents thereof as well as additional items. References to “or” may be construed as inclusive so that any terms described using “or” may indicate any of a single, more than one, and all of the described terms.

### Electronic Package of the Background Art

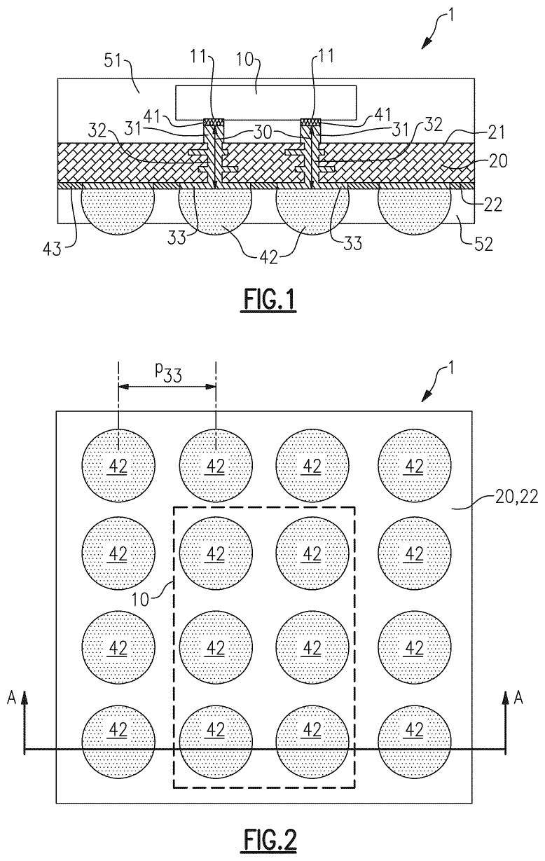

FIGS. 1 and 2 show a cross-sectional schematic view and a schematic plan view of an electronic package 1 of the background art. FIG. 1 is a view through section A-A of FIG. 2. The electronic package 1 has a semiconductor component 10 in the form of a semiconductor die mounted to an upper surface 21 of a substrate panel 20. Interfaces 11 are provided on the underside of the semiconductor die 10, as shown in FIG. 1. Each interface 11 is coupled to a corresponding metallic pillar 31 by portions of solder 41. Each pillar 31 is integrally formed with a corresponding via 32 extending through the thickness of the substrate panel 20 between upper and lower surfaces 21, 22 of the panel. In turn, each via 32 is integrally formed with a corresponding metallic contact pad 33 provided on the lower surface 22 of the substrate panel 20. As can be seen, a unitary, single-piece structure 30 is formed by the successive combination of pillar 31, via 32 and contact pad 33. A ball grid array of solder balls 42 is provided on the lower surface 22 of the substrate panel 20. Each one of the solder balls 42 is soldered onto a respective one of the metallic contact pads 33. The metallic contact pads 33 are arranged in a grid pattern of rows and columns, in which the successive ones of the contact pads are separated from each other by a predetermined pitch ‘p₃₃’. As the solder balls 42 are centrally positioned on respective ones of the contact pads 33, it follows that the pitch ‘p₃₃’ also corresponds to the pitch between successive ones of the solder balls 42. A layer of solder mask 43 is provided on the lower surface 22 of the substrate panel 20. Apertures are provided through the layer of solder mask 43 corresponding to the locations of the contact pads 33. The apertures in the solder mask 43 allow each solder ball 42 to be fused with a respective one of the contact pads 33.

The semiconductor die 10 is covered by an upper side mold structure 51 provided over the upper surface 21 of the substrate panel 20. The array of solder balls 42 is partially covered by a lower side mold structure 52 provided over the lower surface 22 of the substrate panel 20. A portion of each solder ball 42 protrudes through the lower side mold structure 52. The upper and lower side mold structures 51, 52 are formed of materials which are thermally insulative compared to the materials used to form the pillar 31, via 32 and contact pad 33.

FIG. 2 shows the semiconductor die 10 in broken outline. During operation, heat is generated by the semiconductor die 10. The combination of each solder portion 41 and unitary single piece structure 30 acts to conduct heat away from the respective interface 11 of the semiconductor die 10 across the thickness of the substrate panel 20 to a corresponding one of the solder balls 42. It will be appreciated that the level of cooling provided to the semiconductor die 10 by this conductive heat transfer is limited by the size and heat capacity of the discrete solder balls 42. Further, the dimensions of the solder balls 42 are dictated by their primary function of serving as a means for connecting the electronic package 1 to a separate circuit board (not shown).

### Electronic Package and Features Thereof According to Aspects of the Present Disclosure

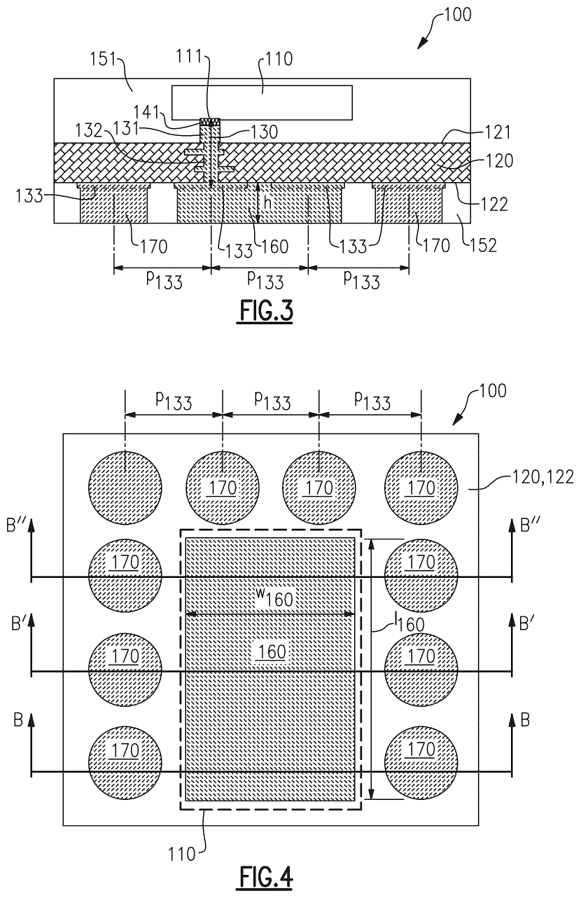

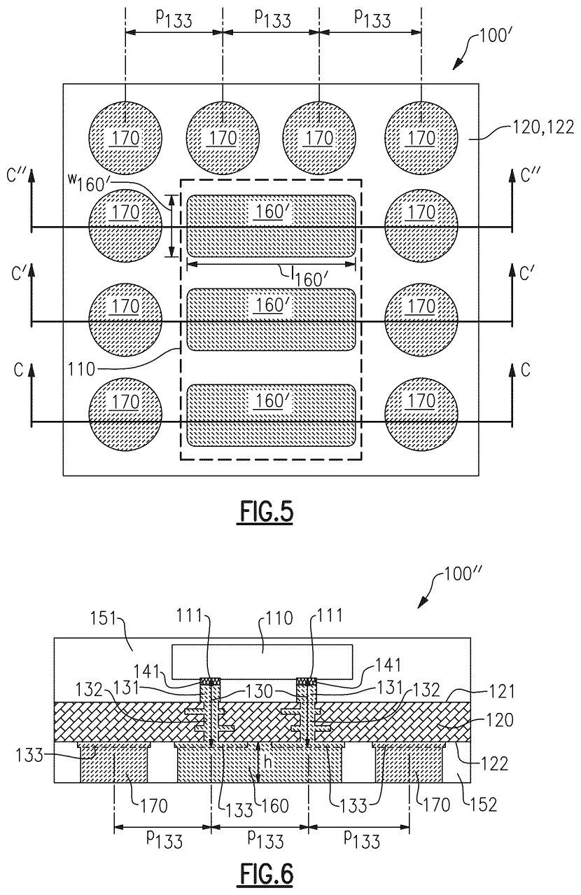

FIGS. 3 and 4 show a cross-sectional schematic view and a plan view of a first example of an electronic package 100 according to aspects of the present disclosure. FIG. 3 is representative of the view through any one of sections B-B, B′-B′ and B″-B″ of FIG. 4.

The electronic package 100 has a substrate panel 120, the panel having a thickness defined between opposing upper and lower surfaces 121, 122. The electronic package 100 is a dual-sided electronic package. The electronic package 100 may also be referred to as a dual-sided molded package module, or a package module.

The substrate panel 120 is generally planar in form. The substrate panel 120 may have a laminate construction. The substrate panel 120 may include a ceramic substrate. The ceramic substrate may include a low temperature co-fired ceramic substrate. However, it will be appreciated that other materials may be used to form the substrate panel 120. The substrate panel 120 may define a printed circuit board.

A semiconductor component 110 in the form of a semiconductor die is mounted to the upper surface 121 of the substrate panel 120. The semiconductor die 110 defines an integrated circuit. In other embodiments, the semiconductor component 110 may be any electronic component which generates heat during its operation and is adapted for mounting to a surface of the substrate panel 120. FIG. 3 shows an interface 111 located on the underside of the semiconductor die 110. The interface 111 is coupled with a corresponding metallic pillar 131 by a portion of solder 141 located therebetween. The pillar 131 is generally cylindrical in shape. However, in other embodiments the pillar 131 may have a profile other than cylindrical. The pillar 131 is integrally formed with a corresponding metallic track 132 embedded within and extending through the thickness of the substrate panel 120 between the upper and lower surfaces 121, 122 of the panel. The metallic track 132 may be or form part of a via incorporated into the structure of the substrate panel 120. In turn, the metallic track 132 is integrally formed with a corresponding metallic contact pad 133 provided on the lower surface of the substrate panel 120. In turn, the metallic contact pad 133 is integrally formed with a thermally conductive element 160 formed or arranged on the lower surface 122 of the substrate panel 120. FIG. 3 shows the thermally conductive element 160 spanning between two adjacent ones of the metallic contact pads 133. The boundaries between the metallic pillar 131, metallic track 132, metallic contact pad 133 and the thermally conductive element 160 are shown in broken outline in FIG. 3.

For interface 111 illustrated in the cross-sectional view of FIG. 3, the successive combination of solder portion 141, metallic pillar 131, metallic track 132 and metallic contact pad 133 define a thermally conductive pathway 130 extending between the interface 111 of the semiconductor die 110 and the thermally conductive element 160. For the illustrated embodiment of FIG. 3, the pillar 131, track 132, contact pad 133 and thermally conductive element 160 are each formed of copper, with copper being thermally and electrically conductive. At an ambient room temperature of 2020 C., copper has a thermal conductivity of about 401 W/m° C. and an electrical conductivity of about 59.6×10⁶ Siemens per metre (S/m). In alternative embodiments, materials other than copper may be used for one or more of the pillar 131, track 132, contact pad 133 and thermally conductive element 160. To allow for the efficient conduction of heat into the thermally conductive element 160, the materials employed for the pillar 131, track 132 and contact pad 133 should be thermally conductive. In some embodiments, the interface 111 of the die 110 also serves as an input/output for electrical or data signals, with the pillar 131, track 132, contact pad 133 and thermally conductive element 160 potentially forming part of a signal pathway to/from the interface 111 of the die 110. Where the pillar 131, track 132, contact pad 133 and thermally conductive element 160 form part of a signal pathway to/from the interface 111 of the die 110, materials having an appropriate level of electrical conductivity will be selected for the pillar 131, track 132, contact pad 133 and thermally conductive element 160.

The metallic contact pads 133 form part of a grid of the metallic contact pads 133 provided on the lower surface 122 of the substrate panel 120, with successive ones of the pads 133 separated from each other by a pitch ‘p₁₃₃’ of 1 mm. It will be understood that in other embodiments the pitch may be greater or less than 1 mm. Each of the metallic contact pads 133 defines an electrically conductive node. Those ones of the contact pads 133 not forming part of the thermally conductive pathways 130 instead define a seat for an interconnection element 170. The interconnection elements 170 are provided to allow for connection of the electronic package 100 to a separate circuit board, although they may also serve as signal paths for transmission of electrical or data signals. For the embodiment described the interconnection elements 170 are in the form of posts formed of copper, in common with material used for the contact pads 133. The interconnection elements 170 are formed by a process of electroplating onto the surface of the contact pads 133. In other embodiments, metallic materials other than copper may be used for the posts 170. For the illustrated embodiment, the interconnection elements 170 are cylindrical in shape. However, in other embodiments, the interconnection elements 170 may have a geometric profile other than cylindrical.

The thermally conductive element 160 of the electronic package 100 of FIG. 3 is in the form of single rectangular block of copper. As will be appreciated from FIG. 4, the thermally conductive element 160 is located on the lower surface 122 of the substrate panel 120 within the footprint of the semiconductor die 110 disposed on the upper surface 121 of the substrate panel. With FIG. 3 being representative of the view through any one of sections B-B, B′-B′, and B″-B″ of FIG. 4, the electronic package 100 has three thermally conductive pathways 130 extending between respective interfaces 111 of the die 110 and the thermally conductive element 160—one thermally conductive pathway 130 being present in each of cross-sections B-B, B′-B′, and B″-B″. However, in other examples, a single thermally conductive pathway 130 may extend between the die 110 and the thermally conductive element 160; for example, the single thermally conductive pathway may form part of one of sections B-B, B′-B′ and B″-B″ of FIG. 4.

Upper and lower side mold structures 151, 152 are applied over the respective upper and lower surfaces 121, 122 of the substrate panel 120 to encapsulate components mounted on the surfaces 121, 122. The upper side mold structure 151 is applied to fully encapsulate all of the components mounted on the upper side 121 of the substrate panel 120, such as the semiconductor die 110. The lower side mold structure 152 is initially applied to fully encapsulate all of the components mounted on the lower side 122 of the substrate panel 120, including the thermally conductive element 160 and the interconnection elements 170. However, in a subsequent step, a grinding operation or similar is performed on the lower side mold structure 152 to expose surfaces of the thermally conductive element 160 and the interconnection elements 170 through the lower side mold structure 152. FIG. 3 shows the electronic package 100 after removal of material from the lower side mold structure 152 to expose the thermally conductive element 160 and interconnection elements 170. FIG. 3 shows exposed surfaces of the thermally conductive element 160 and the interconnection elements 170 formed flush with an exposed surface of the lower side mold structure 152. Top and bottom surfaces of the electronic package 100 are generally planar and parallel to each other. An epoxy material may be used for the upper and/or lower side mold structures 151, 152, although it will be appreciated that in alternative embodiments other materials may be used for the mold structures 151, 152 that provide similar levels of physical protection to the die 110 and other electrical components of the electronic package 110. In some alternative embodiments, solder balls may be used in place of the interconnection elements 170.

During operation of the semiconductor die 110, heat generated by the die is conducted away from the die via the interfaces 111. The heat is conducted through each of the three thermally conductive pathways 130 into the thermally conductive element 160.

The thermally conductive element 160 extends over the lower surface 122 of the substrate panel 120 by a distance greater than the pitch ‘p₁₃₃’ between successive ones of the metallic contact pads 133. As can be understood from FIGS. 3 and 4, the rectangular block of material forming the thermally conductive element 160 extends over a length ‘l’ and a width ‘w’ corresponding generally to the surface area occupied by a grid of six interconnection elements 170 or metallic contact pads 133 arranged in a grid pattern of three elements or pads long by two elements or pads wide. It will be appreciated that in other embodiments, the thermally conductive element 160 may extend over a lesser or greater number of the metallic contact pads 133 than illustrated in FIG. 4. As the interconnection elements 170 are centrally disposed on respective contact pads 133, the pitch ‘p₁₃₃’ of the contact pads 133 also defines the pitch between successive ones of the interconnection elements 170, which is 1 mm for the illustrated embodiment. For the illustrated embodiment of FIGS. 3 and 4, the length ‘l’, width ‘w’ and height ‘h’ dimensions of the thermally conductive element 160 are 3 mm, 2 mm and 0.120 mm (120 microns) respectively, corresponding to an enclosed volume of 0.72 mm³ for the thermally conductive element 160. It will be appreciated that the dimensions and enclosed volume referred to above are for the purposes of illustration only and are non-limiting. The thermally conductive element 160 provides a large single body of material for receiving heat from the semiconductor die 110 via the thermally conductive pathway 130. In effect, the thermally conductive element 160 is a heat sink for the semiconductor die 110. It will be appreciated that in other embodiments, the dimensions and shape of the thermally conductive element 160 may differ from those described for the electronic package 100 of FIGS. 3 and 4. Further, as described above, the number of thermally conductive pathways 130 thermally coupling the semiconductor component 110 to the thermally conductive element 160 may be greater or lesser in number than three. It will be appreciated that the number of thermally conductive pathways 130 and/or the dimensions of the thermally conductive element 160 will be influenced by any one or more of the dimensions, heat output and heat tolerance of the semiconductor component 110.

FIG. 5 is a plan schematic representation of an electronic package 100′, being a variant of electronic package 100. Electronic package 100′ differs from electronic package 100 in that three elongate thermally conductive bars of copper 160′ are used in place of a single block of copper 160. Each of the thermally conductive bars 160′ is thermally coupled to an interface 111 of the semiconductor die 110 by one of the thermally conductive pathways 130. Each of the thermally conductive bars 160′ has a length ‘l’ of 2 mm, a width ‘w’ of 0.4 mm and a height ‘h’ of 0.120 mm (120 microns), thereby defining an enclosed volume of 0.096 mm³ for each one of the bars 160′. Again, it will be appreciated that the dimensions and enclosed volume referred to above are for the purposes of illustration only and are non-limiting. So, in other embodiments, the dimensions and shape of the thermally conductive bars 160′ may differ from those described for the electronic package 100′. It will be understood that FIG. 3 is also representative of section C-C, C′-C′ and C″-C″ of the electronic package 100′ of FIG. 5, with each section containing a different one of the thermally conductive bars 160′ in place of the single thermally conductive body 160.

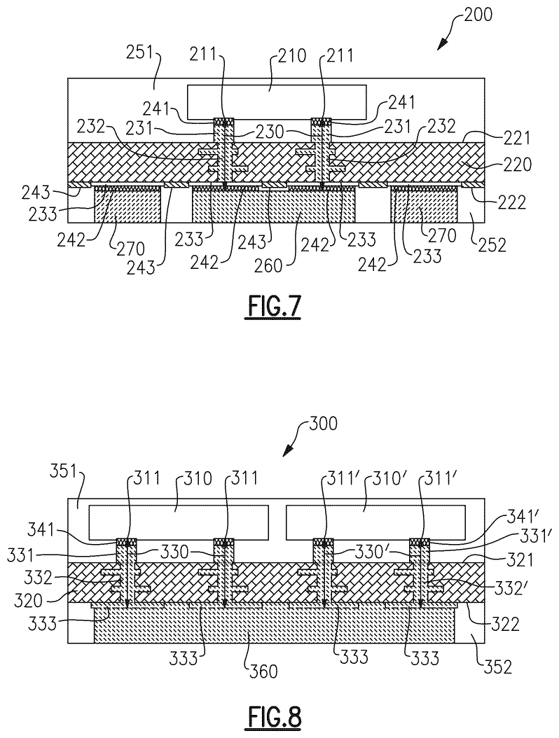

FIG. 6 shows a cross-sectional schematic view of a further example of an electronic package 100″ according to aspects of the present disclosure. The feature numbering used for the features of electronic package 100 is retained for the features of electronic package 100″. The electronic package 100″ is substantially the same as the electronic package 100 of FIG. 3, but differs in the cross-section view of FIG. 6 illustrating two distinct thermally conductive pathways 130, each one of the thermally conductive pathways 130 extending between a respective interface 111 on the underside of the die 110 and the thermally conductive element 160. With FIG. 6 being representative of the view through any one of sections B-B, B′-B′, and B″-B″ of FIG. 4, the electronic package 100″ has six thermally conductive pathways 130 extending between respective interfaces 111 of the die 110 and the thermally conductive element 160—two thermally conductive pathways 130 being present in each of cross-sections B-B, B′-B′, and B″-B″.

It will be appreciated that the number of thermally conductive pathways 130 extending between the die 110 and the thermally conductive element 160 may vary according to various factors, including but not limited to the thermal output of the die 110, the heat tolerance of the die 110 and the physical dimensions of the die 110. The number of thermally conductive pathways 130 may therefore differ from those illustrated in the figures.

FIG. 7 shows a cross-sectional schematic view of a further example of an electronic package 200 according to aspects of the present disclosure. Features in common with electronic package 100 are referred to with like reference signs but commencing with numeral “2” instead of “1”. Electronic package 200 differs from electronic package 100 in that thermally conductive element 260 is provided as a preformed block, strip or bar of material, which is fused to respective metallic contact pads 233 arranged on the lower surface 222 of the substrate panel 220 by intermediate portions of solder 242. FIG. 7 shows the thermally conductive element 260 spanning between two adjacent ones of the metallic contact pads 233. The contact pads 233 are exposed through apertures defined in a layer of solder mask 243 applied over the lower surface 222 of the substrate panel 220. In a similar manner to electronic package 100, each metallic pillar 231 is integrally formed with a corresponding metallic track 232 (for example, a via) embedded within and extending through the thickness of the substrate panel 220 between the upper and lower surfaces 221, 222 of the panel. In turn, the metallic track 232 is integrally formed with a corresponding metallic contact pad 233 provided on the lower surface of the substrate panel 220. The successive combination of solder portion 241, metallic pillar 231, metallic track 232, metallic contact pad 233 and solder portion 242 define a thermally conductive pathway 230 extending between the interface 211 of the semiconductor die 210 and the thermally conductive element 260. The cross-sectional view of FIG. 7 shows the semiconductor die 210 thermally coupled to the thermally conductive element 260 by two distinct ones of the thermally conductive pathways 230.

FIG. 8 shows a cross-sectional schematic view of a further example of an electronic package 300 according to aspects of the present disclosure. Features in common with electronic package 100 are referred to with like reference signs but commencing with numeral “3” instead of “1”. Electronic package 300 differs from electronic package 100 in that two semiconductor components 310, 310′ are mounted to the upper surface 321 of the substrate panel 320. Both semiconductor components 310, 310′ are thermally coupled to a common thermally conductive element 360 by multiple thermally conductive pathways 330 (for semiconductor component 310), 330′ (for semiconductor component 310′). The semiconductor components 310, 310′ are in the form of a semiconductor die. FIG. 8 shows semiconductor die 310 thermally coupled to thermally conductive element 360 by two distinct ones of the thermally conductive pathways 330. FIG. 8 also shows semiconductor die 310′ thermally coupled to the same thermally conductive element 360 by two distinct ones of the thermally conductive pathways 330′. Each thermally conductive pathway 330 extending between the interface 311 of the die 310 and the thermally conductive element 360 is formed by the successive combination of solder portion 341, metallic pillar 331, metallic track 332 and metallic contact pad 333. Similarly, each thermally conductive pathway 330′ extending between the interface 311′ of die 310′ and the same thermally conductive element 360 is formed by the successive combination of solder portion 341′, metallic pillar 331′, metallic track 332′ and metallic contact pad 333. As can be seen in FIG. 8, the thermally conductive element 360 extends along a majority of the length or width dimension of the substrate panel 320. FIG. 8 shows the thermally conductive element 360 spanning across four successive ones of the metallic contact pads 333. In other embodiments, a single thermal conductive pathway 330, 330′ may extend between each semiconductor die 110, 110′ and the common thermally conductive element 360.

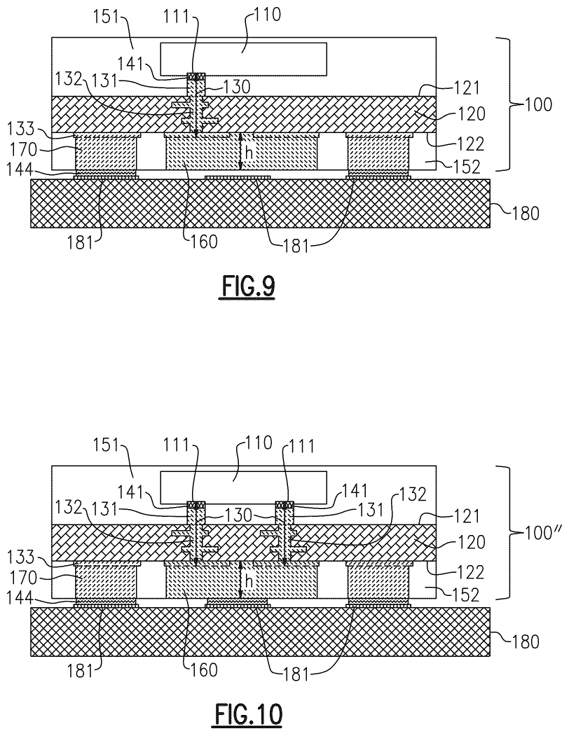

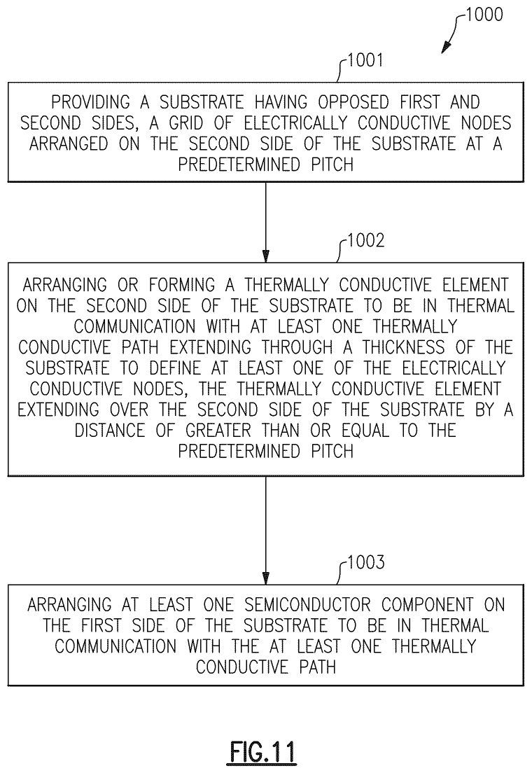

FIG. 9 is a schematic view showing the electronic package 100 of FIG. 3 mounted to a surface of a separate circuit board 180 to form an electronic sub-assembly. Exposed surfaces of the copper posts defining the interconnection elements 170 permit the electronic package 100 to be coupled to the circuit board 180. More specifically, intermediate portions of solder 144 are provided between exposed surfaces of the copper posts 170 and corresponding contact pads 181 provided on the surface of the circuit board 180. For the illustrated embodiment of FIG. 9, the thermally conductive element 160 is not directly coupled to the circuit board 180. However, in an alternative embodiment to that shown in FIG. 9, an intermediate portion of solder 144 may be used to couple an exposed face of the thermally conductive element 160 to a corresponding contact pad 181 of the circuit board 180, thereby allowing for heat flow from the thermally conductive element 160 into the circuit board 180.

FIG. 10 is a schematic view showing the electronic package 100″ of FIG. 6 mounted to a surface of the circuit board 180 to form an electronic sub-assembly. However, in contrast to the electronic sub-assembly of FIG. 9, an intermediate portion of solder 144 is used to couple an exposed face of the thermally conductive element 160 to a corresponding contact pad 181 of the circuit board 180, there allowing heat flow from the thermally conductive element 160 into the circuit board 180.

### Methods for Manufacturing Electronic Packages According to Aspects of the Present Disclosure

FIG. 11 is a flow chart illustrating an exemplary method 1000 of manufacturing an electronic package according to aspects of the present disclosure. The method 1000 may be applied to any of the electronic packages referred to in preceding paragraphs of this disclosure, such as electronic packages 100, 100′, 100″, 200, 300. The steps of the method 1000 may also be understood by reference to the preceding paragraphs of the present disclosure describing the structure and formation of electronic packages 100, 100′, 100″, 200, 300.

The method 1000 has a step 1001 of providing a substrate having opposed first and second sides, a grid of electrically conductive nodes arranged on the second side of the substrate at a predetermined pitch. For example, the substrate may be the substrate panel 120 previously described in relation to FIGS. 3 and 4, with the opposed first and second sides being the upper and lower surfaces 121, 122 of the substrate panel 120. By way of further example, the grid of electrically conductive nodes may be the grid of metallic contact pads 133 described in relation to FIGS. 3 and 4.

The method also has a step 1002 of arranging or forming a thermally conductive element on the second side of the substrate to be in thermal communication with at least one thermally conductive path extending through a thickness of the substrate to define at least one of the electrically conductive nodes. The thermally conductive element extends over the second side of the substrate by a distance of greater than or equal to the predetermined pitch; for example, by a distance exceeding the pitch ‘p₁₃₃’ of the metallic contact pads 133 for the electronic package 100 of FIG. 3. By way of example, the thermally conductive element may be the thermally conductive element 160 previously described in relation to FIGS. 3 and 4. By way of example, the thermally conductive path may correspond to the metallic track 132 of the substrate panel 120 of FIG. 3. Step 1002 may further include electroplating onto the thermally conductive path (for example onto the metallic track 132 or the metallic contact pad 133 illustrated in FIG. 3) to progressively build up and form the thermally conductive element. Alternatively, step 1002 may include providing a preformed block, strip or bar of thermally conductive material (for example, the thermally conductive element 260 of FIG. 7) and fixing it to the thermally conductive paths (for example, by use of portions of solder 242 as employed in the embodiment of FIG. 7).

The method also has a step 1003 of arranging at least one semiconductor component on the first side of the substrate to be in thermal communication with the least one thermally conductive path. For example, as shown in FIGS. 3 and 4, a metallic pillar 131 may be positioned between a semiconductor die 110 and the metallic track 132 incorporated into the structure of the substate panel 120 to ensure thermal communication between an interface 111 of the die 110 and the metallic track 132.

The performing of steps 1001, 1002, 1003 results in an electronic package (for example, electronic package 100) in which the semiconductor component (for example, semiconductor die 110) provided on the first side of the substrate is thermally coupled to a thermally conductive element (for example, thermally conductive element 160) provided on the opposite second side of the substrate.

The method 1000 may include a further step of arranging a first side mold structure over the first side of the substrate to encapsulate the semiconductor component. Similarly, the method may include a further step of arranging a second side mold structure over the second side of the substrate to at least partially encapsulate the thermally conductive element. By way of example, the first and second side mold structures may correspond to the mold structures 151, 152 described above in relation to the embodiment of FIG. 3. The first and second side mold structures serve to provide a level of physical protection to components mounted on the first and second sides of the substrate. As described in preceding paragraphs, where application of the second side mold structure initially results in the thermally conductive element being fully obscured from view beneath the surface of the second mold structure, a grinding operation may be performed to expose a surface of the thermally conductive element through the second side mold structure. Exposure of a surface of the thermally conductive element through the second side mold structure may allow the electronic package to be mounted to a circuit board by the use of solder fused between the exposed surface of the thermally conductive element and a surface of the circuit board.

The electronic package resulting from the method 1000 may correspond to the electronic packages 100, 100′, 100″, 200, 300 described above, but is not limited thereto. As noted above, it will be appreciated that the above discussion of the technical features, materials and other characteristics of the different features of the electronic packages 100, 100′, 100″, 200, 300 is applicable to the method 1000 of manufacture outlined in FIG. 11.

### Exemplary Devices Incorporating Electronic Package According to Aspects of the Present Disclosure

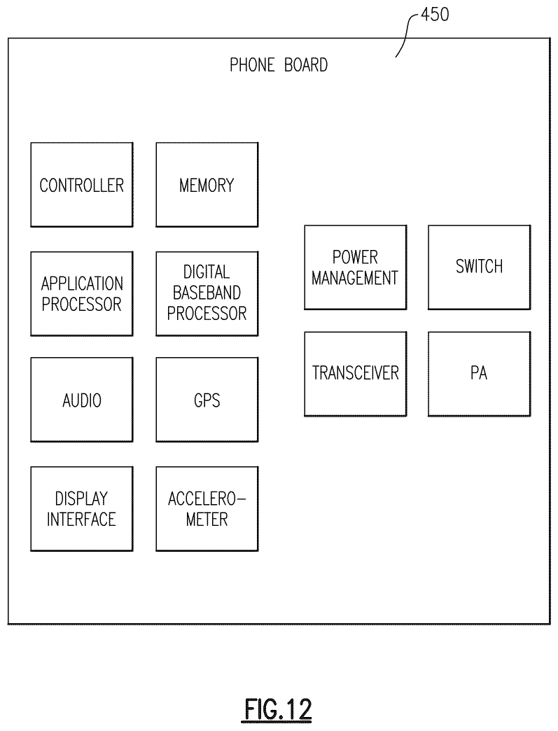

FIG. 12 shows an embodiment of a circuit board 450, such as a wireless phone board, which may include one or more dual-sided molded package modules within the scope of the present disclosure, such as the dual-sided molded package module 100 of FIG. 3. Non-limiting examples of package modules that can benefit from such packaging features as disclosed herein include, but are not limited to, a controller module, an application processor module, an audio module, a display interface module, a memory module, a digital baseband processor module, a global positioning system (GPS) module, an accelerometer module, a power management module, a transceiver module, a switching module, and a power amplifier module. So, each of the package modules depicted for the wireless phone board 450 of FIG. 12 may correspond to the dual-sided molded package module 100 of FIG. 3.

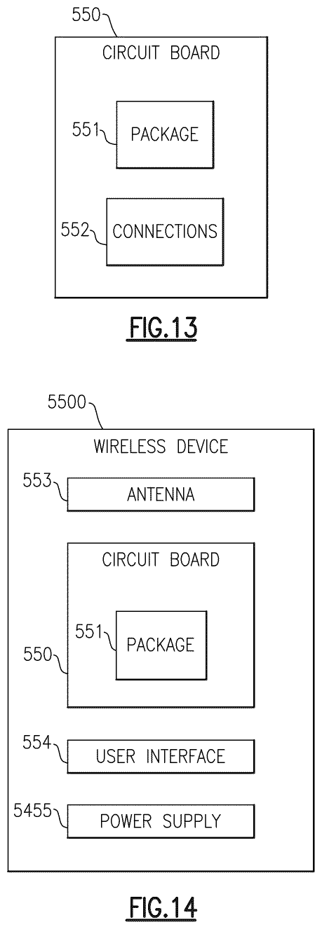

FIG. 13 schematically depicts a circuit board 550 having a package module 551 mounted thereon in the manner described herein; by way of example, the package module 551 may correspond to the dual-sided molded package module of FIG. 3. The circuit board 550 may also include other features, such as a plurality of connections 552 to facilitate operations of various packages mounted thereon. FIG. 14 schematically depicts a wireless device 5500 (for example, a cellular phone) having a circuit board 550 (for example, a phone board). The circuit board 550 is shown to include a package 551 mounted thereon in the manner described herein; for example, the package 551 may correspond to the dual-sided molded package module 100 of FIG. 3. The wireless device 5500 is shown to further include other components, such as an antenna 553, a user interface 554, and a power supply 555.

It will be noted that the figures are for illustrative purposes only, and are not to scale.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

1. An electronic package for mounting to a circuit board, the electronic package comprising:
a substrate having opposed first and second sides;
at least one semiconductor component disposed on the first side of the substrate;
a grid of electrically conductive nodes arranged on the second side of the substrate at a predetermined pitch;
at least one thermally conductive element disposed on the second side of the substrate, the thermally conductive element coupled to at least one thermally conductive pathway, the thermally conductive pathway extending between the semiconductor component and the second side of the substrate through a thickness of the substrate to define at least one of the electrically conductive nodes and thermally couple the semiconductor component to the thermally conductive element, the thermally conductive element extending over the second side of the substrate by a distance of greater than or equal to the predetermined pitch.

2. The electronic package of claim 1 wherein the at least one thermally conductive pathway includes at least first and second thermally conductive pathways extending between the semiconductor component and the second side of the substrate through the thickness of the substrate, each of the first and second thermally conductive pathways thermally coupling the semiconductor component to the thermally conductive element.

3. The electronic package of claim 2 wherein each of the first and second thermally conductive pathways define respective ones of the electrically conductive nodes.

4. The electronic package of claim 1 wherein the thermally conductive pathway includes an intra-substrate portion extending between the opposed first and second sides of the substrate.

5. The electronic package of claim 4 wherein the thermally conductive element is integrally formed as a unitary piece with the intra-substrate portion.

6. The electronic package of claim 5 wherein the thermally conductive element is electroplated onto the intra-substrate portion.

7. The electronic package of claim 4 wherein the thermally conductive pathway includes a first intermediate element thermally coupling the intra-substrate portion of the thermally conductive pathway to the semiconductor component.

8. The electronic package of claim 4 wherein the thermally conductive pathway includes a second intermediate element thermally coupling the intra-substrate portion of the thermally conductive pathway to the thermally conductive element.

9. The electronic package of claim 8 wherein the second intermediate element includes or consists of a metallic post substantially formed of a non-solder material.

10. The electronic package of claim 4 wherein the intra-substrate portion and the thermally conductive element are substantially formed of copper.

11. The electronic package of claim 4 wherein the intra-substrate portion includes a metallic contact pad disposed on the second side of the substrate.

12. The electronic package of claim 11 wherein the intra-substrate portion further includes a via extending from the first side of the substrate, the metallic contact pad coupled to the via.

13. The electronic package of claim 12 wherein the metallic contact pad is integrally formed as a unitary piece with the via.

14. The electronic package of claim 1 wherein the at least one semiconductor component includes first and second semiconductor components disposed on the first side of the substrate.

15. The electronic package of claim 14 wherein a first one or set of thermally conductive pathways extends between the first semiconductor component and the thermally conductive element and a second one or set of thermally conductive pathways extends between the second semiconductor component and the thermally conductive element to thereby thermally couple each of the first and second semiconductor components to the thermally conductive element.

16. The electronic package of claim 1 wherein the thermally conductive element is disposed on the second side of the substrate to lie within a surface area footprint of the semiconductor component disposed on the first side of the substrate.

17. The electronic package of claim 1 wherein the thermally conductive element has a length dimension that is greater than 60%, or 70%, or 80% of a length or a width dimension of the semiconductor component.

18. The electronic package of claim 1 wherein a length dimension of the thermally conductive element is no more than 110%, or 100%, or 90% of a length dimension of the semiconductor component.

19. The electronic package of claim 1 wherein the at least one thermally conductive element includes a group of thermally conductive elements disposed on the second side of the substrate, each one of the group of thermally conductive elements coupled to at least one corresponding thermally conductive pathway extending between the semiconductor component and the respective thermally conductive element.

20. An electronic device comprising an electronic sub-assembly, the electronic sub-assembly comprising:
a circuit board; and
an electronic package mounted to the circuit board;
the electronic package including:
a substrate having opposed first and second sides;
at least one semiconductor component disposed on the first side of the substrate;
a grid of electrically conductive nodes arranged on the second side of the substrate at a predetermined pitch;
at least one thermally conductive element disposed on the second side of the substrate, the thermally conductive element coupled to at least one thermally conductive pathway, the thermally conductive pathway extending between the semiconductor component and the second side of the substrate through a thickness of the substrate to define at least one of the electrically conductive nodes and thermally couple the semiconductor component to the thermally conductive element, the thermally conductive element extending over the second side of the substrate by a distance of greater than or equal to the predetermined pitch.
